(19) United States
(12) Patent Application Publication
(10) Pub. No.: US 2020/0159356 A1
(43) Pub. Date: May 21, 2020

(54) DISPLAY DEVICE

(71) Applicant: Japan Display Inc., Tokyo (JP)

(72) Inventors: Yusuke TADA, Tokyo (JP); Hajime Akimoto, Tokyo (JP)

(21) Appl. No.: 16/773,066

(22) Filed: Jan. 27, 2020

Related U.S. Application Data
(63) Continuation of application No. PCT/JP2018/029905, filed on Aug. 9, 2018.

(30) Foreign Application Priority Data
Aug. 10, 2017 (JP) 2017-155333

(51) Int. Cl. G06F 3/041; G06F 3/044; H01L 51/56; H01L 51/52; H01L 27/32

(52) U.S. Cl. CPC G06F 3/0412; G06F 3/0445; H01L 51/56; G06F 2203/04112; H01L 51/5253; H01L 27/323; G06F 2203/04103; G06F 3/0446

(57) ABSTRACT

A display device includes a substrate having an insulating surface, a pixel part having a plurality of pixels on the insulating surface, a terminal part including a first terminal arranged in a region outside the pixel part on the insulating surface, and a second terminal arranged in a region inside the first terminal, a wiring part including a first wiring arranged between the pixel part and the terminal part, a sensing part overlapped on the pixel part, and a sealing part covering the pixel part and the wiring part. The first wiring included in the wiring part is electrically connected to a first detection electrode at an opening provided in the second inorganic insulating layer, and the first wiring extends to an outer region of the second inorganic insulating layer and is electrically connected to the second terminal.

### CROSS-REFERENCE TO RELATED APPLICATIONS

This application is based upon and claims the benefit of priority from the prior Japanese Patent Application No. 2017-155333, filed on Aug. 10, 2017, and PCT Application No. PCT/JP2018/029905 filed on Aug. 9, 2018, the entire contents of which are incorporated herein by reference.

### FIELD

One embodiment of the present invention relates to a display device having an input function. One embodiment of the invention disclosed herein relates to a wiring structure of a display device having embedded a touch sensor.

### BACKGROUND

Electronic devices that are operated by touching images such as icons displayed on the screen are becoming popular. The display panels used in such electronic devices are also referred to as touch panels (or touch screens). In the touch panel, the touch sensor of the capacitive type is adopted. The capacitance type touch sensor, there is one that detects a change in the capacitance between a pair of sensor electrodes called Tx electrode and Rx electrode as an input signal.

Conventional touch panel has a structure in which a touch sensor panel and a display panel are overlapped. However, the structure in which two panels are overlapped, it becomes a problem that the thickness of the display device increases. For example, in a display device that bends or folds, such as referred to as a flexible display, a structure in which the touch sensor panel and the display panel are overlapped becomes a factor that hinders flexibility.

Therefore, a structure in which an electrode functioning as a touch sensor is embedded the display panel is disclosed. For example, in a display panel using an organic electroluminescent element (hereinafter, also referred to as “organic EL element”), a first detection electrode and a second detection electrode are arranged across the inorganic insulating film provided as a sealing film, a display device called in-cell type provided with a touch sensor in the panel is disclosed (Japanese Laid-Open Patent Publication No. 2015-050245).

When the touch sensor is to be embedded in the display panel, the wirings to be connected to the detection electrode is required, the number of wirings formed in the display panel increases. Further, the display element provided on the display panel is protected by a sealing layer. Therefore, it is necessary to provide a detection electrode and the wiring without deteriorating the sealing performance of the sealing layer.

### SUMMARY

A display device in an embodiment according to the present invention includes a substrate having an insulating surface, a pixel part having a plurality of pixels on the insulating surface, a terminal part including a first terminal arranged in a region outside the pixel part on the insulating surface, and a second terminal arranged in a region inside the first terminal, a wiring part including a first wiring arranged between the pixel part and the terminal part, a sensing part overlapped on the pixel part, and a sealing part covering the pixel part and the wiring part. The sealing part includes a first inorganic insulating layer, an organic insulating layer, and a second inorganic insulating layer in this order from the substrate side, and the organic insulating layer is arranged in a region overlapping the pixel part, and the first inorganic insulating layer and the second inorganic insulating layer are arranged in a region overlapping the pixel part and the wiring part. The sensing part includes a first detection electrode arranged at an upper side of the first inorganic insulating layer and at a lower side of the second inorganic insulating layer; and a second detection electrode arranged at an upper side of the second inorganic insulating layer. The first wiring included in the wiring part is electrically connected to the first detection electrode at an opening provided in the second inorganic insulating layer, and the first wiring extends to an outer region of the second inorganic insulating layer and is electrically connected to the second terminal.

A manufacturing method for a display device in an embodiment according to the present invention, the method includes forming a pixel part arranged a plurality of pixels on a substrate having an insulating surface, forming a terminal part including a first terminal in a region outside the pixel part on the insulating surface, forming a second terminal between the pixel part and the terminal part on the insulating surface, forming a first inorganic insulating layer covering the pixel part, forming a first detection electrode layer extending in a first direction on the first inorganic insulating layer, forming an organic insulating layer covering the first detection electrode layer, forming a second inorganic insulating layer covering the organic insulating layer, removing the first inorganic insulating layer and the second inorganic insulating layer on the second terminal, and forming an opening exposing the first detection electrode layer in the second insulating layer, and forming a second detection electrode layer extending in a second direction intersecting with the first direction on the second inorganic insulating layer, and forming a first wiring connected to the first detection electrode and the second terminal in the opening provided in the second inorganic insulating layer.

### BRIEF DESCRIPTION OF DRAWINGS

FIG. 1 is a perspective view showing a configuration of a display device according to an embodiment of the present invention;

FIG. 2 is a perspective view showing a configuration of a pixel area of the display device according to an embodiment of the present invention;

FIG. 3 is a plan view showing a configuration of a display device according to an embodiment of the present invention;

FIG. 4 is a plan view showing a configuration of a peripheral region of the display device according to an embodiment of the present invention;

FIG. 5 is a cross-sectional view taken along line X1-X2 of FIG. 3 showing the configuration of a display device according to an embodiment of the present invention;

FIG. 6 is a cross-sectional view showing a configuration of a pixel area of the display device according to an embodiment of the present invention;

FIG. 7 shows a flowchart illustrating a method of manufacturing a display device according to an embodiment of the present invention;

FIG. 8 is a plan view showing a configuration of a peripheral region of the display device according to another embodiment of the present invention;

FIG. 9 is a cross-sectional view showing a configuration of a display device according to another embodiment of the present invention;

FIG. 10 is a plan view showing a configuration of a peripheral region of the display device according to still another embodiment of the present invention;

FIG. 11 is a cross-sectional view showing a configuration of a display device according to still another embodiment of the present invention;

FIG. 12 is a cross-sectional view showing a manufacturing process of a display device according to an embodiment of the present invention;

FIG. 13 is a cross-sectional view showing a manufacturing process of a display device according to an embodiment of the present invention;

FIG. 14 is a cross-sectional view showing a manufacturing process of a display device according to an embodiment of the present invention; and

FIG. 15 is a cross-sectional view showing a manufacturing process of a display device according to an embodiment of the present invention.

### DESCRIPTION OF EMBODIMENTS

Hereinafter, the embodiments of the present invention will be described while referencing the drawings. However, the present invention may be implemented in many different ways, therefore interpretation should not be limited to the content exemplified in the embodiments below. In order to provide a clearer description, some components of the drawings such as the width, thickness, shape, etc. of each part are represented schematically. These drawings are merely examples and do not limit the interpretation of the present invention. In this specification and each of the drawings, elements similar to previously described elements are marked with the same symbols (numbers followed by a, b, and the like) and detailed descriptions are omitted accordingly. Furthermore, characters labeled as “first” and “second” are symbols used to distinguish each element, and do not have any further meaning unless otherwise specified.

In this specification, when certain components or regions are described as being “above” or “below” other components or regions, as long as there are no limitations, it does not necessarily mean they are directly above or below. This description includes cases in which a component or region is located higher or lower than another component or region. In other words, other components or regions are located between the component or region being described and the component or region above or below. Further, in the description below, unless otherwise noted, in a sectional view, the side on which the second substrate is located with respect to the substrate will be described as “above” and the other side will be described as “below”.

### First Embodiment

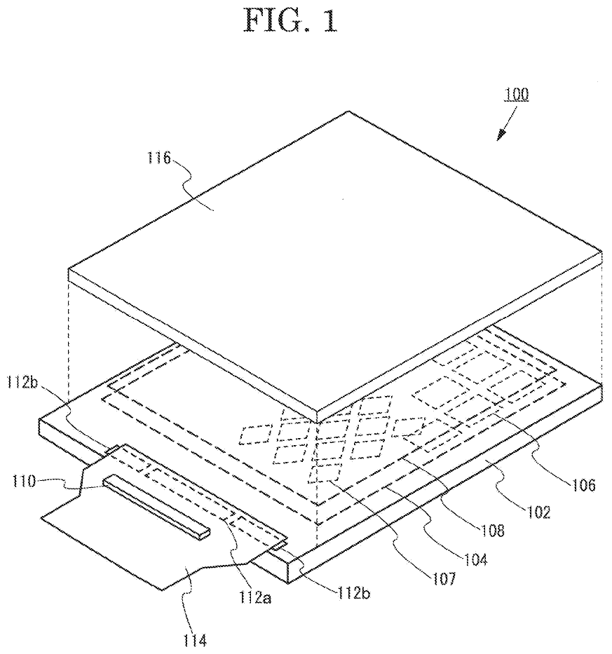

FIG. 1 shows a perspective view showing a display device 100 according to an embodiment of the present invention. The display device 100 is arranged a pixel part 104 and a touch sensor 108 on a first surface of the substrate 102 having an insulating surface. The pixel part 104 is arranged a plurality of pixels 106. A plurality of pixels 106 is arranged, for example, in row and column directions, in pixel part 104. The touch sensor 108 is overlapped on the pixel part 104. In other words, the touch sensor 108 is arranged to overlap a plurality of pixels 106. The touch sensor 108 includes a plurality of detection electrodes 107 arranged in a matrix, each connected in a row or column direction. Here, each of the plurality of pixels 106 and the touch sensor 108 are schematically represented, and the magnitude relation thereof is not limited to that described in FIG. 1.

The display device 100 has a first terminal part 112a in which a video signal or the like is input, a second terminal part 112b in which a signal of the touch sensor 108 is input and output. The first terminal part 112a and the second terminal part 112b is disposed at one end in one main surface of the substrate 102 having an insulating surface. The first terminal part 112a and the second terminal part 112b and a plurality of terminal electrodes are arranged along the end of the substrate 102 having an insulating surface. A plurality of terminal electrodes of the first terminal part 112a and the second terminal part 112b is connected to the flexible printed wiring substrate 114. A drive circuit 110 outputs a video signal to the pixel 106. The drive circuit 110 is attached to the first surface of the substrate 102 or to a flexible printed wiring substrate 114.

The substrate 102 having an insulating surface is formed of a member such as glass, plastics (polycarbonate, polyethylene terephthalate, polyimide, polyacrylate, etc.). When the substrate 102 is made of plastic, it is possible to fabricate the display device 100 having flexibility by thinning the substrate. That is, by using a plastic substrate as the substrate 102, it is possible to realize a flexible display.

Above the pixel part 104 and the touch sensor 108, a polarizing plate 116 including a polarizer may be provided. For example, the polarizer 116 is composed of a polarizer that exhibits circularly polarized light. The polarizer 116 is formed of a film substrate including a polarizer. By providing the polarizing plate 116 overlapped on the pixel part 104, it is possible to prevent reflection (mirroring) of the display screen.

Although omitted in FIG. 1, the pixel 106 is constituted by including a display element and a circuit element. The touch sensor 108 is preferably capacitive type. A sensing part of the capacitive type touch sensor include of a first detection electrode (Tx wiring) and a second detection electrode (Rx wiring). The display device 100 is provided with an interlayer insulating layer between the pixel part 104 and the touch sensor 108, so that the pixel electrode and the detection electrode are arranged so as not to be short-circuited.

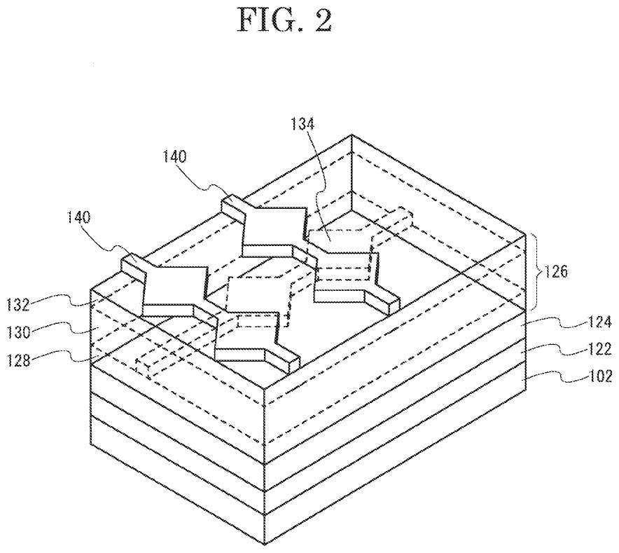

FIG. 2 is a perspective view illustrating the configuration of the pixel part 104 and the touch sensor 108 arranged thereon. As shown in FIG. 2, the pixel part 104 includes a circuit element layer 122 in which a circuit element is provided on the substrate 102, and a display element layer 124 in which a display element is provided. A sealing layer 126 provided with the detection electrodes for the touch sensor is arranged over the display element layer 124. The sealing layer 126 is provided so as to cover the upper surface of the pixel area when the observer views the display screen in the normal direction.

The circuit element layer 122 includes an interlayer insulating layer. The interlayer insulating layer insulates the wirings provided in the different layers. The interlayer insulating layer includes at least one layer of inorganic interlayer insulating layer and at least one layer of organic interlayer insulating layer. The inorganic interlayer insulating layer is formed of inorganic insulating materials such as silicon oxide, silicon nitride, silicon oxynitride, aluminum oxide and the like. The organic interlayer insulating layer is formed by organic insulating materials such as acrylic, polyimide, and the like. The circuit element layer 122 includes a transistor as an active element and a capacitor and a resistor as a passive element, and further includes wirings connecting these elements. The circuit element layer 122 has a structure in which these elements and wirings are embedded in the interlayer insulating layer.

The display element layer 124, as the display element, a light emitting element, or an electro-optical element for expressing an electro-optical effect by the applying a voltage is used. When an organic EL element is used as a light emitting element, the display element layer 124 includes a pair of electrodes distinguished as an anode and a cathode, an organic layer including an organic EL material, and an insulating partition layer separating between adjacent organic EL elements. The organic EL element is electrically connected to the transistor of the circuit element layer 122.

The sealing layer 126 has a structure in which a plurality of insulating films is laminated. FIG. 2 shows a structure in which the sealing layer 126 has a structure in which a first inorganic insulating layer 128, an organic insulating layer 130 and a second inorganic insulating layer 132 are stacked. The sealing layer 126 has an insulating layer laminated structure formed of different materials. The sealing layer 126 has a high sealing property due to such a structure. For example, the sealing layer 126 can compensate for degradation in sealing performance due to defects in the first inorganic insulating layer 128 by the organic insulating layer 130 embedding the defective portion and further providing the second inorganic insulating layer 132, even if the defects are included in the first inorganic insulating layer 128. In the case of the second inorganic insulating layer 132 is preferably provided so as to cover the entire surface of the pixel part 104 and at least a portion of the outer area of the pixel part 104. The first inorganic insulating layer 128 and the second inorganic insulating layer 132 are preferably provided to cover further outer regions of the organic insulating layer 130. The outer peripheral end portion of the first inorganic insulating layer 128 and the second inorganic insulating layer 132 may not necessarily coincide with each other.

In the first detection electrode 134 and second detection electrode 140 that make up the sensing part of the touch sensor 108, the first detection electrode 134 is embedded in the sealing layer 126 and the second detection electrode 140 is positioned above the sealing layer 126. Although not shown in FIG. 2, the upper surface of the second detection electrode 140 may be coated by the overcoat layer 184.

The first detection electrode 134 is arranged within the sealing layer 126 so as to extend in a first direction, and the second detection electrode 140 is arranged over the sealing layer 126 so as to extend in a second direction intersecting the first direction. The first direction can be any direction. For example, the first direction can be a direction along the column direction corresponding to the arrangement of the pixels. In this case, the second direction can be a direction along the array of pixel row directions. A plurality of first detection electrodes 134 and a plurality of second detection electrodes 140 are arranged in the sensing part. In this embodiment, a group by the plurality of first detection electrodes 134 is also referred to as a first detection electrode pattern, a group by the plurality of second detection electrodes 140 is also referred to as a second detection electrode pattern. In FIG. 2, only a portion of one of the plurality of first detection electrodes 134 and one of the plurality of second detection electrodes 140 are exemplified. The plurality of first detection electrodes 134 and the plurality of second detection electrodes 140 are arranged over substantially the entire pixel part 104.

The first detection electrode 134 and the second detection electrode 140 are arranged across the second inorganic insulating layer 132 that constitutes at least the sealing layer 126. The first detection electrode 134 and the second detection electrode 140 are insulated by at least the second inorganic insulating layer 132. That is, the first detection electrode 134 is arranged at least on the lower layer than the second inorganic insulating layer 132, and the second detection electrode 140 is arranged on the upper layer than the at least the second inorganic insulating layer 132. The first detection electrode 134 and the second detection electrode 140 are insulated by being arranged across at least the second inorganic insulating layer 132, and electrostatic capacitance is caused between the both detection electrodes. The sensing part of the touch sensor 108 detects a change in electrostatic capacitance that occurs between the first detection electrode 134 and the second detection electrode 140 to determine the presence or absence of a touch.

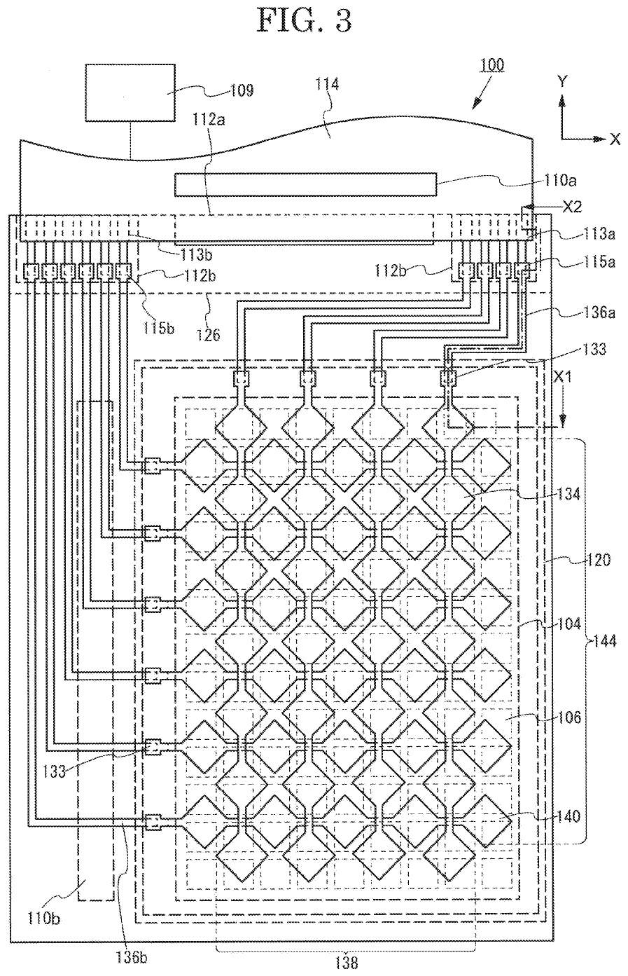

FIG. 3 shows a plan view of the display device 100. FIG. schematically illustrates the arrangement of the first detection electrode 134 and the second detection electrode 140. FIG. 3, for convenience of explanation, shows the vertical direction with respect to the paper as Y direction, the horizontal direction as X direction.

FIG. 3 shows the plurality of first detection electrodes 134 extending in the Y direction and the plurality of second detection electrodes 140 extending in the X direction. A group of the plurality of first detection electrodes 134 as the first detection electrode pattern 138, a group of the plurality of second detection electrodes 140 as the second detection electrode pattern 144.

Shapes of the first detection electrode 134 and the second detection electrode 140 are optional. The first detection electrode 134 and the second detection electrode 140 may be rectangular (stripe) shaped or may have a shape articulated with diamond-shaped electrodes as shown in FIG. 3. By adopting the detection electrode having a shape in which such a rectangular (stripe) type to rhomboid (diamond) type are arranged continuously, improvement of the detection sensitivity of the touch sensor 108 can be achieved.

The first detection electrode pattern 138 and the second detection electrode pattern 144 are arranged in an area overlapping the pixel part 104. In other words, the first detection electrode 134 and the second detection electrode 140 are arranged so as to overlap at least a portion of the pixel 106 (a portion of the light emitting elements provided in the pixel). By thus arranging the first detection electrode pattern 138 and the second detection electrode pattern 144, while displaying an image such as an icon on the pixel part 104, it is possible to sense the presence or absence of touch by the touch sensor 108.

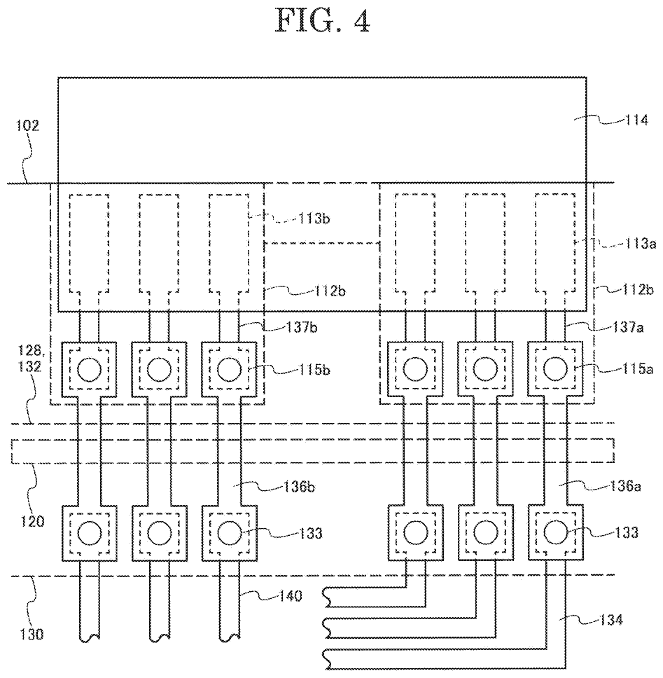

FIG. 4 is a plan view showing a configuration of a peripheral region of the display device 100 according to an embodiment of the present invention. FIG. 4 is a partially enlarged view of a plan view shown in FIG. 3. Referring to FIGS. 3 and 4, the pixel part 104 is covered with the sealing layer 126. The first detection electrode 134 is electrically connected to a first wiring 136a at an opening 133 provided on the sealing layer 126 on the exterior of the pixel part 104. The first wiring 136a is electrically connected to a second terminal 115a which is a connecting terminal for a touch panel provided in the second terminal part 112b. The second terminal 115a is electrically connected by a first terminal 113a and a second wiring 137a which are connected to the flexible printed wiring substrate 114.

The second detection electrode 140 is electrically connected to a first wiring 136b provided on the exterior of the pixel part 104. The first wiring 136b is electrically connected to the second terminal 115b of the second terminal part 112b. The configurations of first wiring 136b, the first terminal 113b and the second terminal 115b are the same as the configurations of the first wiring 136a, the first terminal 113a and the second terminal 115a, respectively.

In FIG. 3, the drive circuit 110b included in the peripheral region 118 outside the pixel part 104 is provided with a plurality of transistors (not shown). For example, a plurality of transistors includes an n-channel transistor, or a p-channel transistor, or both. The drive circuit is formed using one or both of the n-channel transistor and the p-channel transistor.

The substrate 102 is provided with an opening region 120 surrounding the pixel part 104. In this opening region 120, organic materials between the substrate 102 and the second inorganic insulating layer is removed. In other words, the interlayer insulating layer on the substrate 102 includes at least one layer of inorganic interlayer insulating layer and organic interlayer insulating layer, having a stacked region in which the inorganic interlayer insulating layer and the organic interlayer insulating layer are stacked, and the opening region in which organic interlayer insulating layer is removed and the inorganic interlayer insulating layer remains. Details of the opening region 120 are described by the cross-sectional structures of the pixel part 104, which will be described later. The first wiring 136a, 136b may be drawn from the pixel part 104 through the top of the opening region 120 to the peripheral edge of the substrate 102.

As shown in FIG. 4, in the display device 100 according to an embodiment of the present invention, the opening region 120 is arranged at a position crossing between the opening 133, the second terminal 115a, 115b in a plan view. In the present embodiment, the first wiring 136a, 136b are extended to the perimeter of the substrate 102 through over the opening region 120 from the pixel part 104.

As shown in FIG. 3, the second terminal part 112b is connected to the touch sensor controller 109 via a flexible printed wiring substrate 114. That is, the detection signals obtained by the first detection electrode 134 and the second detection electrode 140 are transmitted to the second terminal part 112b by the first wiring 136a, 136b, and the second wiring 137a, 137b, and are output to the touch sensor controller 109 through the flexible printed wiring substrate 114.

The display device 100 according to an embodiment of the present invention, the first detection electrode pattern 138 and the second detection electrode pattern 144 constituting the sensing part of the touch sensor 108 is provided on the substrate 102. With such a configuration, since it is not necessary to externally attach the touch sensor provided as a separate part, it is possible to reduce the thickness of the display device 100. As shown in FIG. 2, the first detection electrode 134 is provided so as to be buried in the sealing layer 126 and the second detection electrode 140 is provided so as to abut upon the sealing layer 126. This arrangement reduces the thickness of the display device 100 because the dielectric layer for forming the capacitance between the first detection electrode 134 and the second detection electrode 140 is replaced by a portion of the sealing layer 126.

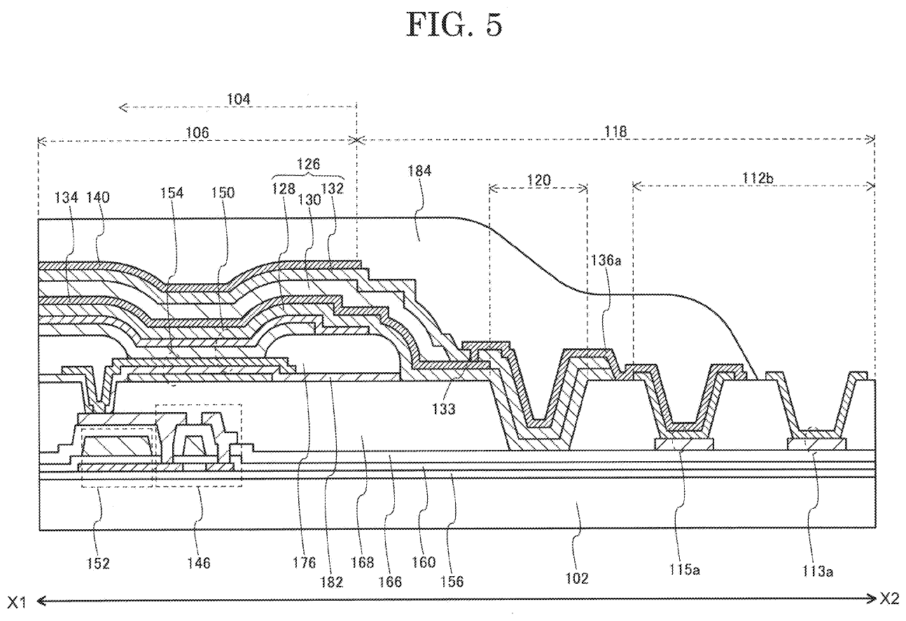

FIG. 5 shows a cross-sectional structure of the display device 100 according to an embodiment of the present invention. FIG. 5 schematically shows cross-sectional structures of the peripheral regions 118 located outside of the pixel part 104 and the pixel part 104. This cross-sectional structure corresponds to the structure along the X1-X2 line shown in FIG. 3

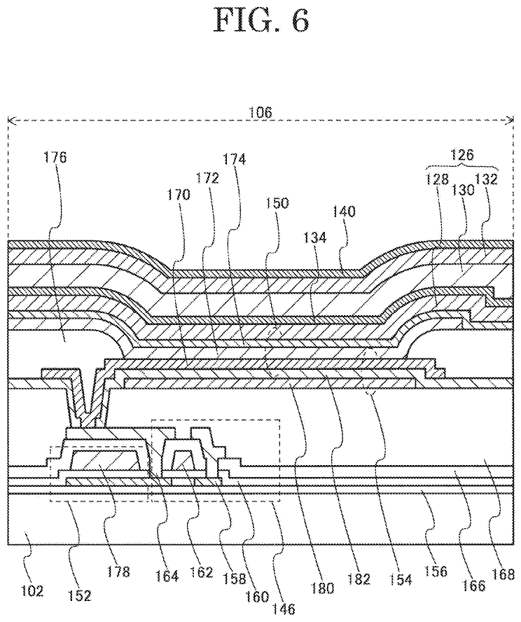

As shown in FIG. 5, the pixel part 104 and the peripheral regions 118 are provided on the substrate 102. The peripheral region 118 includes a wiring part including the first wiring 136a and a second terminal region 112b comprising the first terminal 113a and the second terminal 115a. The peripheral region 118 also includes the opening region 120 formed along the outer periphery of the region where the pixel part 104 and the organic insulating layer 130 are formed. The pixel part 104 includes a transistor 146, an organic EL element 150, a first capacitor element 152, a second capacitor element 154. Details of the pixel 106 including these elements are shown in FIG. 6.

As shown in FIG. 6, the organic EL element 150 is electrically connected to the transistor 146. The transistor 146 controls the current between the source and drain by the video signal applied to the gate, and the luminous intensity of the organic EL element 150 is controlled by this current. The first capacitor element 152 holds the gate voltage of the transistor 146, the second capacitor 154 is provided to prevent the potential of the pixel electrode 170 is inadvertently varied. The second capacitor element 154 is not an essential configuration, and it can be omitted.

As shown in FIG. 6, the underlying an insulating layer 156 is provided on the first surface of the substrate 102. The transistor 146 is provided on the underlying insulating layer 156.

The transistor 146 includes a structure in which a semiconductor layer 158, a gate insulating layer 160, a gate electrode 162 are stacked. The semiconductor layer 158 is formed of amorphous or polycrystalline silicon, or an oxide semiconductor or the like. At least one source drain wiring 164 is provided over the gate electrode 162 via a first insulating layer 166. A second insulating layer 168 as a planarization layer is provided over the upper layer of the at least one source drain wiring 164.

The first insulating layer 166, the second insulating layer 168 is interlayer insulating layer. The first insulating layer 166 is a kind of inorganic interlayer insulating layer and is formed of an inorganic insulating material such as silicon oxide, silicon nitride, silicon oxynitride, aluminum oxide, or the like. The second insulating layer 168 is a kind of organic interlayer insulating layer and is formed of an organic insulating material such as polyimide, acrylic, or the like. The interlayer insulating layer is stacked in the order of the first insulating layer 166, the second insulating layer 168 from the substrate 102 sides. By providing the second insulating layer 168 formed of an organic insulating material on the upper layer of the first insulating layer 166, uneven caused by the transistor 146 or the like is embedded, and the surface is planarized.

An organic EL element 150 is provided on the upper surface of the second insulating layer 168. The organic EL element 150 has a structure in which the pixel electrode 170 electrically connected to the transistor 146 and an organic layer 172 and a counter electrode 174 are stacked. The organic EL element 150 is a two-terminal element, light emission is controlled by controlling the voltage between the pixel electrode 170 and the counter electrode 174. A partition wall layer 176 is provided on the second insulating layer 168 so as to cover the peripheral portion and expose the inner region of the pixel electrodes 170. The counter electrode 174 is provided on the top surface of the organic layer 172. The organic layer 172 is provided from a region overlapping the pixel electrodes 170 to an upper surface portion of the partition wall layer 176. The partition wall layer 176 covers the peripheral portion of the pixel electrode 170, to form a smooth step at the end of the pixel electrode 170 is formed of an organic resin material. As organic resin materials, acrylic and polyimide, etc. are used.

The organic layer 172 is formed of a single layer or multi layers comprising an organic EL material. The organic layer 172 is formed from an organic material of a low molecule system or a polymer system. When using an organic material of the low molecule system, the organic layer 172 is composed of a light emitting layer including an organic EL material, a hole injection layer so as to sandwich the light emitting layer, an electron injection layer, further including a hole transport layer and an electron transport layer. For example, the organic layer 172 can have a structure in which the light emitting layer is sandwiched between the hole injection layer and the electron injection layer. Further, the organic layer 172, in addition to the hole injection layer and the electron injection layer, a hole transport layer, an electron transport layer, a hole block layer, such as an electron block layer may be appropriately added.

In the present embodiment, the organic EL element 150 has a so-called top emission type structure that emits light emitted by the organic layer 172 to the opposing electrode 174 side. Therefore, it is preferable that the pixel electrodes 170 have light reflectivity. The pixel electrodes 170 can be formed of a light reflective metallic material such as aluminum (Al) or silver (Ag), and can be formed of a structure in which a transparent conductive layer made of ITO (Indium Tin Oxide) or IZO (Indium Zinc Oxide) which having excellent hole injection properties and a light reflective metal layer are laminated.

The counter electrode 174 is formed of a transparent conductive film, such as ITO or IZO, which is transparent and conductive so as to transmit light emitted from the organic layer 172. At the interface between the counter electrode 174 and the organic layer 172, a layer comprising an alkaline metal such as lithium or an alkaline earth metal such as magnesium may be provided to enhance the carrier implantability.

The first capacitor element 152 uses the gate insulating layer 160 as a dielectric film, is formed in a region where the semiconductor layer 158 and the first capacitor electrode 178 is overlapped. The second capacitor element 154, the third insulating layer 182 provided between the pixel electrode 170 and the second capacitor electrode 180 is used as a dielectric film, is formed by a second capacitor electrode 180 provided overlapped on the pixel electrode 170 and the pixel electrode. The third insulating layer 182 is formed of an inorganic insulating material such as silicon nitride.

The sealing layer 126 is provided on the upper layer of the organic EL element 150. The sealing layer 126 is provided to prevent moisture or the like from entering the organic EL element 150. The sealing layer 126, from the side of the organic EL element 150 has a structure in which the first inorganic insulating layer 128, the organic insulating layer 130 and the second inorganic insulating layer 132 are laminated. The first inorganic insulating layer 128 and the second inorganic insulating layer 132 are formed of inorganic insulating materials such as silicon nitride, silicon nitride, aluminum oxide, and the like. The first inorganic insulating layer 128 and the second inorganic insulating layer 132, a coating of these inorganic insulating materials, sputtering method, is formed by a plasma-CVD method or the like. The first inorganic insulating layer 128 and the second inorganic insulating layer 132 are formed from 0.1 μm to 10 μm, and preferably from 0.5 μm to 5 μm thick.

The organic insulating layer 130 is preferably formed of acrylic resin, polyimide resin, epoxy resin or the like. The organic insulating layer 130 is provided with a thickness of 20 μm from 1 μm, preferably 10 μm from 2 μm. The organic insulating layer 130 is provided by a coating method such as a spin-coating, or by a vapor deposition method using an organic material source. The organic insulating layer 130 is preferably formed within a predetermined area including the pixel part 104 such that the ends are sealed with the first inorganic insulating layer 128 and the second inorganic insulating layer 132 while covering the pixel part 104. For example, as shown in FIG. 5, the ends (contours) of the organic insulating layer 130 are preferably provided between the pixel part 104 and the opening region 120. Therefore, the organic insulating layer 130 is formed on the entire surface of the substrate 102 by a coating method, and then the outer peripheral region is removed by etching, or a predetermined pattern is preferably formed by vapor deposition (mask deposition) using a mask which opens a surface to be deposited, inkjet printing, flexographic printing, and gravure printing. Furthermore, as shown in FIG. 5, the upper layer of the sealing layer 126 may be provided with an overcoat layer 184 that covers the wiring part and second terminal 115a of the pixel part 104 and the peripheral region 118 and exposes the first terminal 113a.

Although omitted in FIG. 5, the upper surface of the sealing layer 126, the polarizing plate 116 is provided as shown in FIG. 1. The polarizing plate 116, in addition to the polarizer, a color filter layer, a light shielding layer may be appropriately included.

In the touch sensor 108, the first detection electrode 134 is provided between the first inorganic insulating layer 128 and the organic insulating layer 130, and the second detection electrode 140 is provided on top of the second inorganic insulating layer 132. The first detection electrode 134 and the second detection electrode 140 may be transparent electrodes formed of a transparent conductive film to transmit light emitted from the organic EL element 150. ITO or IZO film which are a kind of transparent conductive film are prepared by sputtering method.

The first detection electrode 134 and the second detection electrode 140 may be fabricated as transparent electrodes by a printing method using metal nanowires, in addition to oxide conductive materials such as ITOs, IZOs, and the like, or may be fabricated by mesh metal wiring using metal films. The mesh metal wiring has a structure in which the conductive layer portions constituting the first detection electrode 134 and the second detection electrode 140 are provided only in regions that do not overlap the organic EL element 150. For example, at least one of the electrodes of the first detection electrode 134 and the second detection electrode 140 may be formed of mesh wiring having a laminated structure including a titanium (Ti) layer, an aluminum (Al) layer, and a titanium (Ti) layer.

The first detection electrode 134 may be a mesh wiring formed of metal having a laminated structure including a titanium layer, an aluminum layer and a titanium layer, and the second detection electrode 140 may be a diamond shaped electrode formed of a transparent conductive film such as ITO or IZO. The opening 133 is formed in the second inorganic insulating layer 132 to electrically connect the first detection electrode 134 and the first wiring 136a (or the first wiring 136b) on the second inorganic insulating layer 132. When forming the opening 133, a process of removing the inorganic insulating layer on the first terminal part 112a and the second terminal part 112b at the same time is performed. The size of the opening 133 and the area to remove the inorganic insulating layers on the first terminal part 112a and the second terminal part 112b are different. Therefore, there is a risk that the first detection electrode 134 underneath the opening 133 may be over-etched. However, the first detection electrode 134 can prevent over-etching because titanium is provided on the outermost surface.

When the first detection electrode 134 and the second detection electrode 140 are mesh-metal wirings, the titanium layer, the aluminum layer, and the titanium layer preferably have a stacked structure. Again, the opening 133 is formed in the second inorganic insulating layer 132 to electrically connect the first detection electrode 134 to the first wiring 136a (or the first wiring 136b) on the second inorganic insulating layer 132. When forming the opening 133, a process of removing the inorganic insulating layer on the first terminal part 112a and the second terminal part 112b at the same time is performed. The size of the opening 133, the area for removing the inorganic insulating layer on the first terminal part 112a and the second terminal part 112b is different. Therefore, there is a risk that the first detection electrode 134 underneath the opening 133 may be over etched. However, since titanium is provided on the outermost surface of the first detection electrode 134, it is possible to prevent over etching. Furthermore, even if the wiring for extending from the pixel part 104 to the peripheral region 118 is formed using either one of the first detection electrode 134 and the second detection electrode 140, unlike when forming the wiring with a transparent conductive film such as ITO or IZO, there is no need to consider the film thickness reduction due to etching, thereby eliminating the need for a thick film and realizing a low resistance.

In the present embodiment, since the organic insulating layer 130 is formed on the upper layer of the first detection electrode 134, even if a foreign material is attached after forming a transparent conductive film or the like forming the first detection electrode 134, the foreign material can be coated with the organic insulating layer 130. This prevents shorting of the second detection electrode 140 formed on the organic insulating layer 130 and the first detection electrode 134. Further, since the upper layer of the organic insulating layer 130 is provided with a second inorganic insulating layer 132, it is possible to maintain its function as a sealing layer 126.

As shown in FIG. 3, the opening region 120 is provided between the pixel part 104 and the drive circuit 110b. The opening region 120 includes an opening that penetrates the second insulating layer 168. The opening region 120 is provided along at least one side of the pixel part 104. Preferably, the opening region 120 is provided to surround the pixel part 104. As shown in FIG. 5, the second insulating layer 168 is divided into a pixel part 104 side and the drive circuit 110b side by the opening region 120. In other words, in the opening of the opening region 120, the second insulating layer 168 formed by the organic material is removed.

As shown in FIG. 5, the organic insulating layer 130 that constitutes the sealing layer 126 has an end between the opening region 120 and the pixel part 104. The first inorganic insulating layer 128 and second inorganic insulating layer 132 extend to the exterior of the end of the organic insulating layer 130. Thus, in the outer area of the organic insulating layer 130, structures in which the first inorganic insulating layer 128 and the second inorganic insulating layer 132 are in contact are formed. In other words, the organic insulating layer 130 is sandwiched by the first inorganic insulating layer 128 and the second inorganic insulating layer 132 and has a construction in which the ends are not exposed. With this construction, it is possible to prevent moisture or the like from entering from the end of the organic insulating layer 130.

Thus, by dividing the second insulating layer 168 formed of an organic insulating material in the peripheral region 118 by the opening region 120, the inorganic material layer is arranged so as to cover the side and bottom surfaces of the opening region 120, the sealing structure is formed. By sandwiching the second insulating layer 168 formed of an organic insulating material by a layer of inorganic material, moisture can be prevented from entering the pixel part 104 from the end of the substrate 102. The opening region 120 separating the second insulating layer 168 can function as a moisture blocking region, the structure can be referred to as a “moisture blocking structure”.

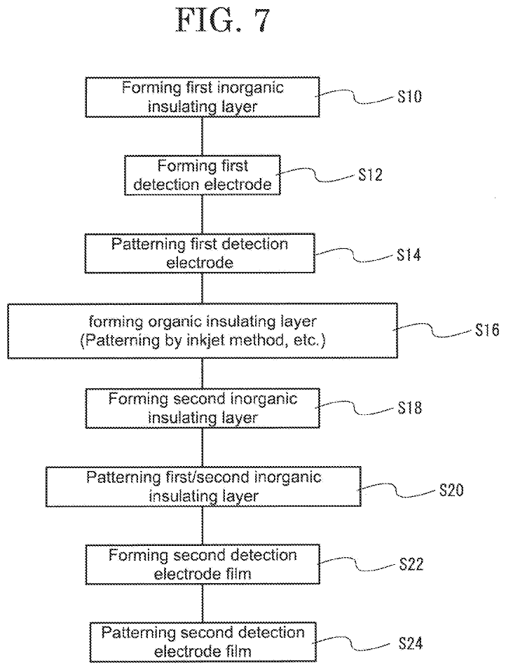

Next, a method of manufacturing the display device 100. FIG. 7 is a flowchart illustrating a process of manufacturing the display device 100 according to an embodiment of the present invention, showing a step of manufacturing the sealing layer 126 and the first detection electrode 134, and the second detection electrode 140.

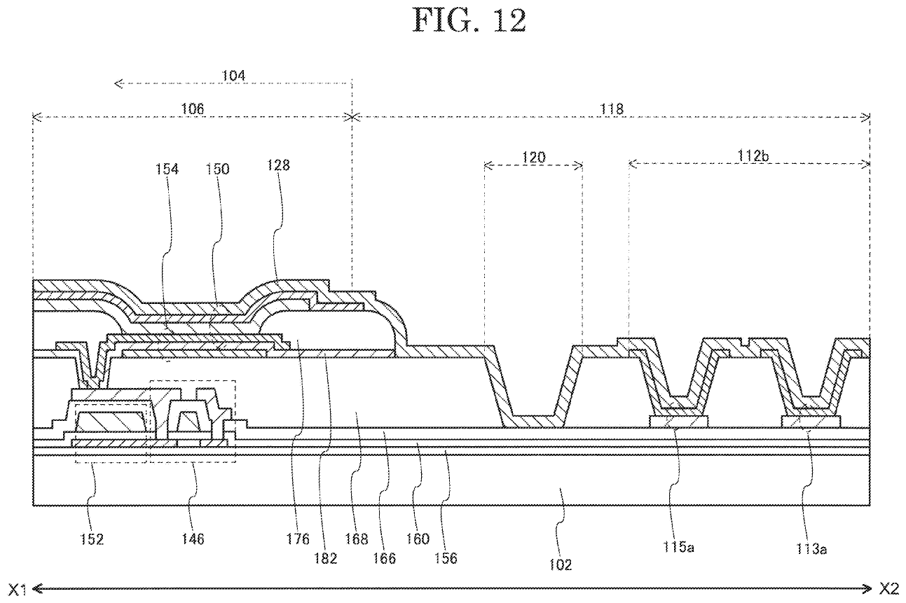

First, after forming the organic EL element 150 on the first surface of the substrate 102 having an insulating surface, to prepare a first inorganic insulating layer 128 (FIG. 7, S10). FIG. 12 shows a cross-sectional view of the display device 100 at this stage. As shown in FIG. 12, on the substrate 102, transistor 146, the organic EL element 150, the first capacitor element 152, the second capacitor element 154, the second terminal 115, the opening region 120 is formed. Thereafter, the first inorganic insulating layer 128 is formed to cover them. The first inorganic insulating layer 128 is fabricated by a vapor deposition method such as a plasma-CVD (Chemical Vapor Deposition) method. The first inorganic insulating layer 128 is made of a silicon nitride film, a silicon nitride oxide film, or the like.

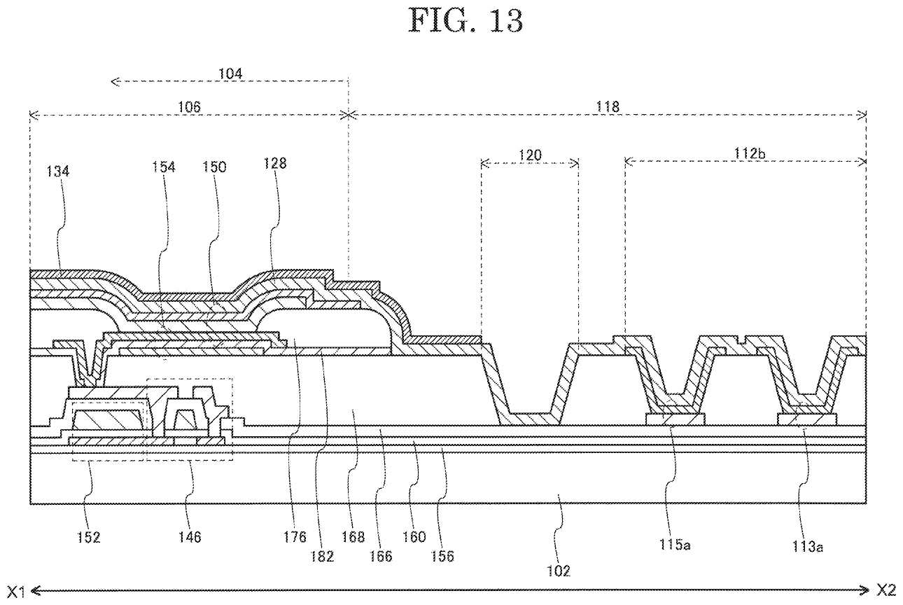

After fabricating the first inorganic insulating layer 128, to fabricate the first detection electrode 134 (FIGS. 7, S12 and S14). As shown in FIG. 13, a first detection electrode 134 is formed over the first inorganic insulating layer 128. To fabricate the first detection electrode 134, first, a transparent conductive film such as IZO is deposited on substantially the entire surface of the first inorganic insulating layer 134 by a sputtering method (FIG. 7 S12). Thereafter, by being patterned into a predetermined shape by the photolithography process, the first detection electrode 134 is formed (FIG. 7, S14).

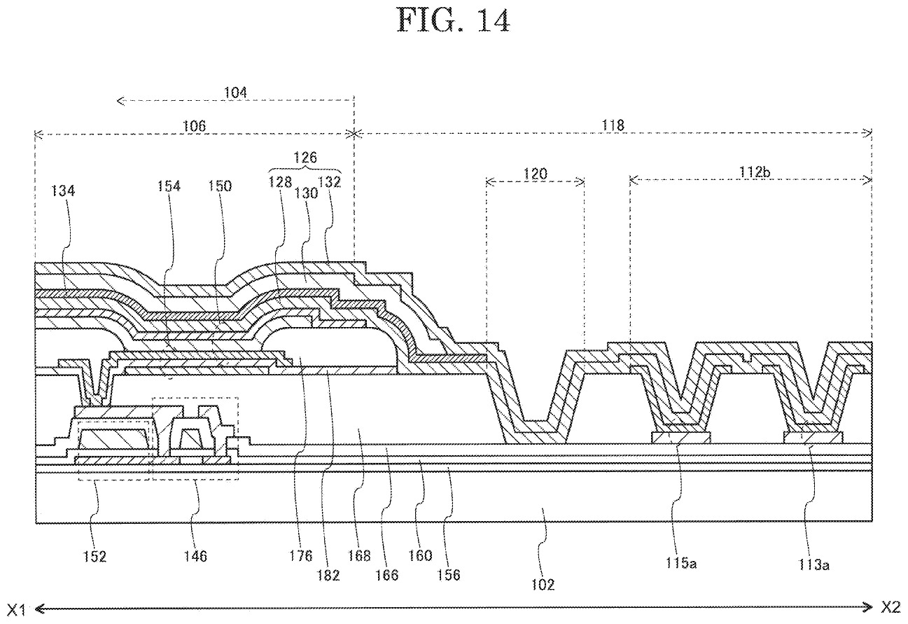

Next, the organic insulating layer 130 is formed by a printing method or the like (FIG. 7, S16). As shown in FIG. 14, the organic insulating layer 130 is formed to cover the pixel part 104 and not protrude from the opening region 120. The organic insulating layer 130 is made by an ink jet method or the like. The organic insulating layer 130 is made by discharging a composition including a precursor of a predetermined organic resin material such as acrylic resin, polyimide resin, epoxy resin, etc., from the ink head, after applying on the pixel part 104, and baking. The organic insulating layer 130 may be formed through a developing process using a photosensitive material.

Then, to form the second inorganic insulating layer 132 (FIG. 7, S18). As shown in FIG. 14, the second inorganic insulating layer 132 is formed on substantially the entire surface of the substrate 102. The second inorganic insulating layer 132 covers the organic insulating layer 130 and is formed so as to cover the first detection electrode 134 in areas where the organic insulating layer 130 is not provided, and further closely with the first inorganic insulating layer 128 in areas outside it.

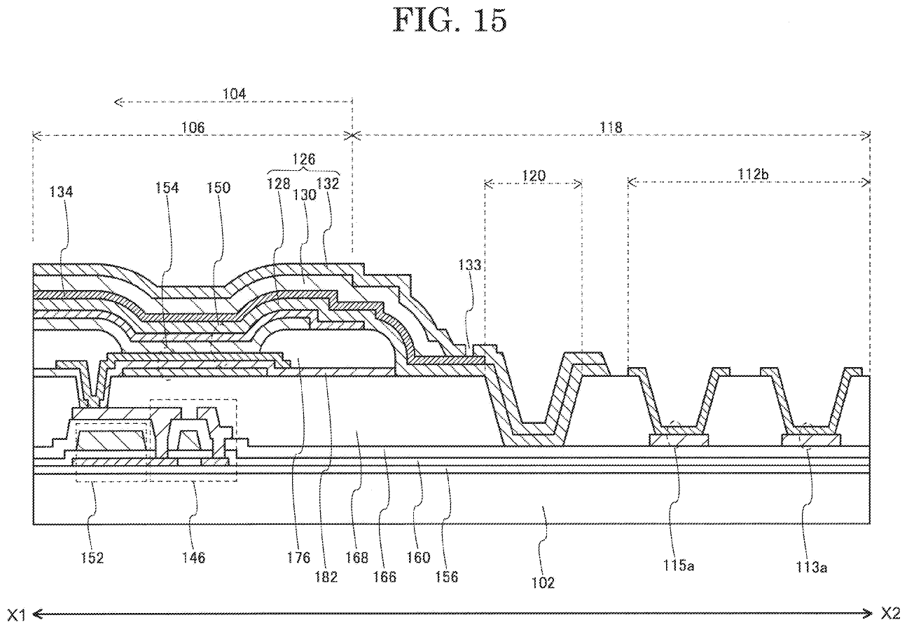

At these stages, the sealing layer 126 is formed. At this stage, the first terminal part 112a and the second terminal part 112b are covered with the sealing layer 126. To remove the sealing layers 126 covering these parts, the steps of patterning the first inorganic insulating layer 128 and the second inorganic insulating layer 132 are performed (FIG. 7, S20). FIG. 15 illustrates the step of forming a mask on the first inorganic insulating layer 132 by a photolithographic process and exposing the second terminal part 112b. At this stage, the second inorganic insulating layer 132 is simultaneously formed with the opening 133 that exposes the first detection electrode 134.

Thereafter, to fabricate the first detection electrode 140 (FIGS. 7, S22 and S24). The second detection electrode 140 is formed over the second inorganic insulating layer 134. To fabricate the second detection electrode 140, first, a transparent conductive film such as IZO is deposited on substantially the entire surface of the second inorganic insulating layer 132 by a sputtering method (FIG. 7 and S22). Thereafter, by being patterned into a predetermined shape by the photolithography process, as shown in FIG. 5, the second detection electrode 140 is formed (FIG. 7, S24).

In the present embodiment, in the step of etching the first inorganic insulating layer and second inorganic insulating layer (S20), when etching the first inorganic insulating layer 128 and the second inorganic insulating layer 132, the opening 133 for exposing the first detection electrode 134 is formed in the second inorganic insulating layer 132. Here, since there is a difference in the etching rate of the inorganic insulating film constituting the metal and the first inorganic insulating layer 128 and the second inorganic insulating layer 132 constituting the first detection electrode 134 (silicon nitride film), the formation of the opening 133 and the inorganic insulating layer removal of the second terminal part 112b, it can be patterned collectively in the same etching process. Thus, reducing the manufacturing process of the display device 100, it is possible to reduce the manufacturing cost.

According to the present embodiment, since the dielectric layer for forming the capacitance between the first detection electrode 134 and the second detection electrode 140 is replaced by a portion of the sealing layer 126, it is possible to be thinning by reducing the number of layers of the thin film. Further, the forming step of the contact hole serving as the opening 133 on the second inorganic insulating layer 132, since the removing step of the inorganic insulating layer on the second terminal part (terminal out) can be patterned collectively, it is possible to reduce the manufacturing costs. Further, when the number of layers of the thin film to be stacked on the pixel part 104 is reduced, the light extraction efficiencies from the pixel 106 are improved. Then, the yield at the time of manufacture of the display device is also improved.

Such a structure is also applicable in a sheet-like substrate in which the substrate 102 is formed of an organic resin material, and it is possible to realize a reduction in the number of layers and a manufacturing process in a flexible display in which a touch panel is incorporated.

### Second Embodiment

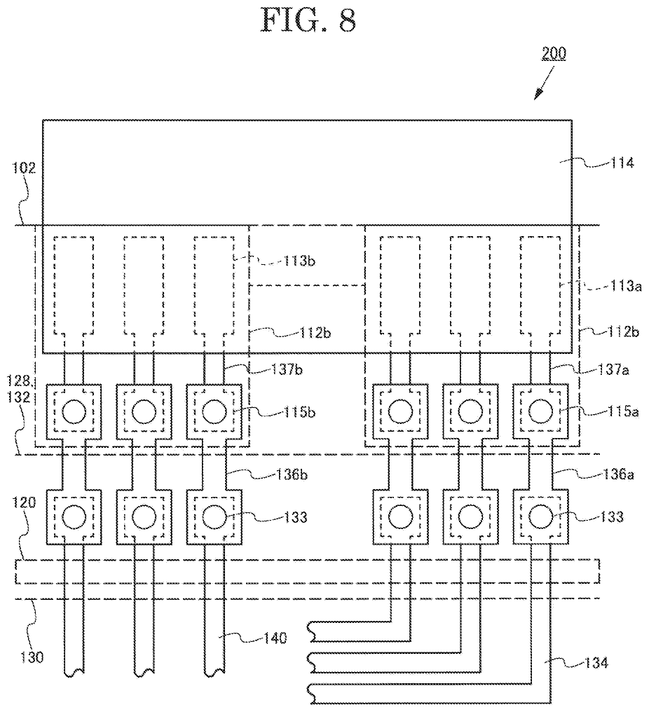

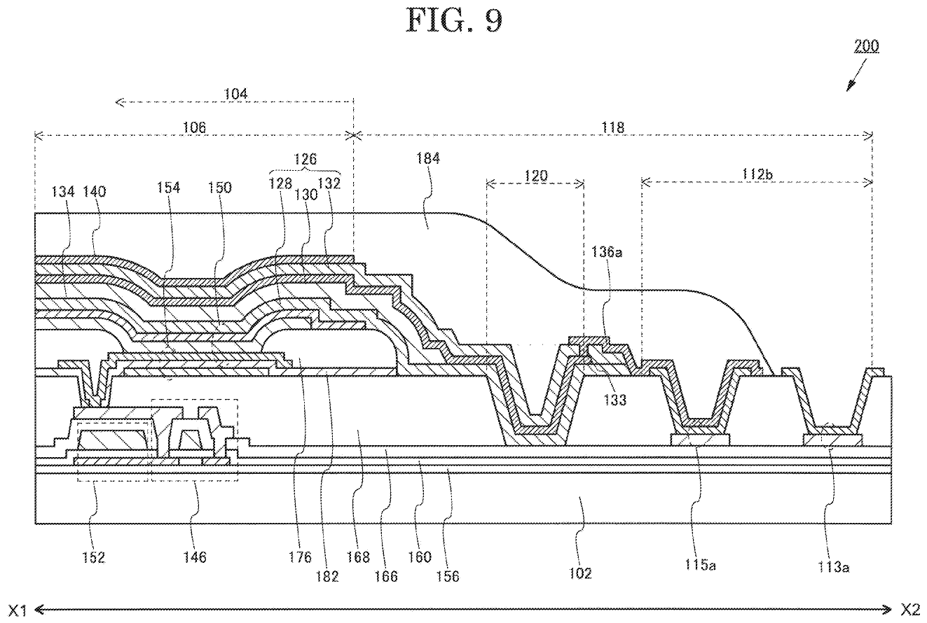

FIG. 8 is a plan view showing a configuration of a peripheral region of a display device 200 according to the present embodiment, FIG. 9 is a cross-sectional view showing a configuration of the display device 200 according to the present embodiment. The display device 200 shown in FIGS. 8 and 9, unlike the display device 100 according to the first embodiment, the opening 133 for connecting the first detection electrode 134 and the first wiring 136 is provided on the outside of the opening region 120. In this embodiment, the first wiring 136 extends across the opening region 120 to the opening 133.

Further, the display device 200 shown in FIGS. 8 and 9 is different from the display device 100 according to the first embodiment, the first detection electrode 134 of the touch sensor 108 is provided between the organic insulating layer 130 and the second inorganic insulating layer 132. Therefore, in the display device 200, the sensing part configured by the first detection electrode 134 and the second detection electrode 140 of the touch sensor 108 is insulated by a second inorganic insulating layer 132 located therebetween. However, the first detection electrode 134 and the second detection electrode 140, because it is sufficient to be insulated by at least the second inorganic insulating layer 132, the first detection electrode 134 as well as the display device 100 in the present embodiment may be provided between the first inorganic insulating layer 128 and the organic insulating layer 130.

Other configurations of the display device 200 according to the present embodiment is similar to the display device 100 according to the first embodiment, to achieve the same effect. Furthermore, the display device 200 according to the present embodiment, up to the vicinity of the second terminal part 102b, since the first detection electrode 134 is arranged sandwiched between the first inorganic insulating layer 128 and the second inorganic insulating layer 132 constituting the sealing layer 126, degradation of the wiring, corrosion is further reduced, it is possible to improve the reliability of the touch sensor.

### Third Embodiment

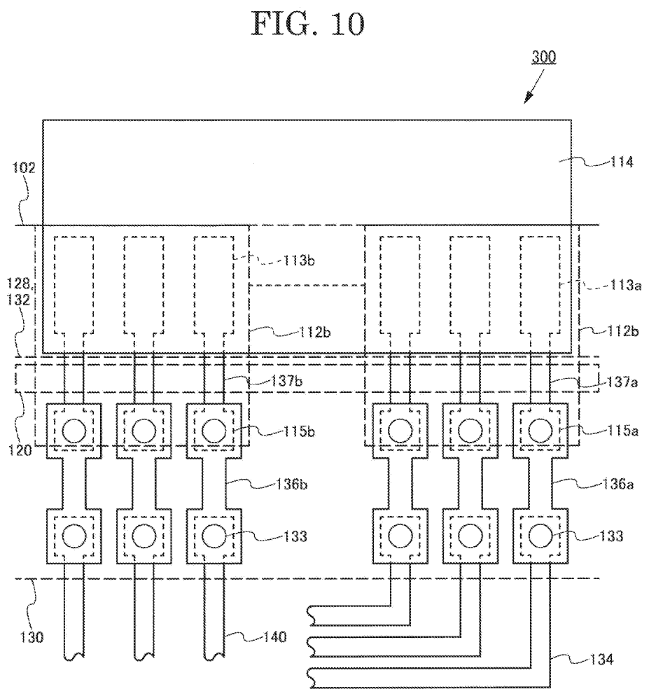

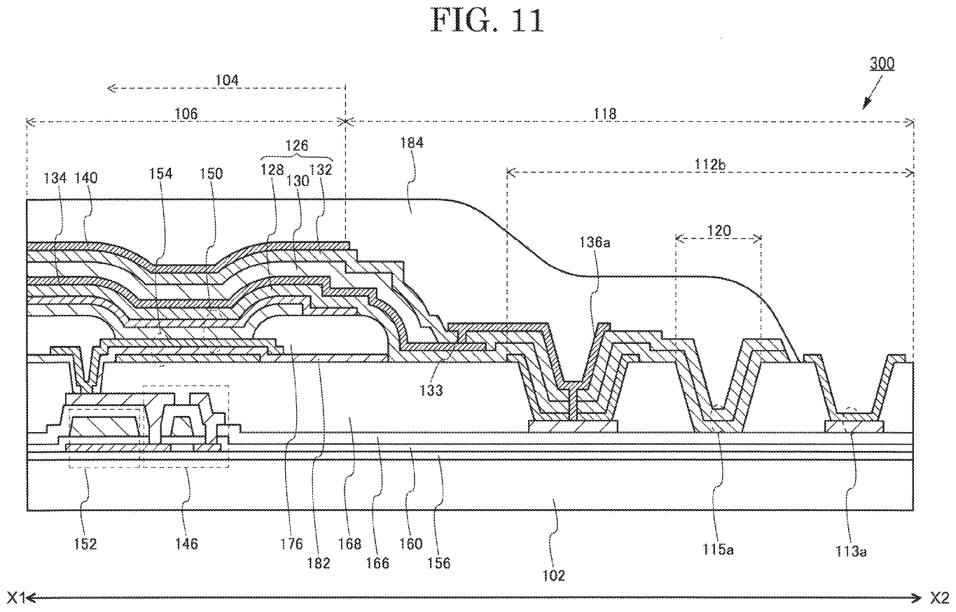

FIG. 10 is a plan view showing a configuration of a peripheral region of a display device 300 according to the present embodiment, FIG. 11 is a cross-sectional view showing a configuration of the display device 300 according to the present embodiment. The display device 300 shown in FIGS. 10 and 11 is different from the display device 100 according to the first embodiment, the opening region 120 is provided on the outside of the second terminal 115a, 115b, and the opening 133 for connecting the first detection electrode 134 and the first wiring 136 is provided on the inside of the second terminal 115a, 115b. Other configurations of the display device 300 is similar to the display device 100.

As shown in FIGS. 10 and 11, the first wiring 136 is connected to the second terminal 115a, 115b through the opening 133 inside the opening region 120 without traversing the opening region 120. Such a wiring arrangement, the wiring length of the first wiring 136 is shortened, and since the first wiring 136 does not need to overcome the step due to the opening region 120, deterioration of the wiring is prevented, it is possible to improve the reliability of the touch sensor.

Other configurations of the display device 300 according to the present embodiment is similar to the display device 100 according to the first embodiment, to achieve the same effect.

What is claimed is:

1. A display device comprising:
a substrate having an insulating surface;
a pixel part having a plurality of pixels on the insulating surface;
a terminal part including a first terminal arranged in a region outside the pixel part on the insulating surface, and a second terminal arranged in a region inside the first terminal;
a wiring part including a first wiring arranged between the pixel part and the terminal part;
a sensing part overlapped on the pixel part; and
a sealing part covering the pixel part and the wiring part,
wherein
the sealing part comprises:
a first inorganic insulating layer, an organic insulating layer, and a second inorganic insulating layer in this order from the substrate side; and
the organic insulating layer is arranged in a region overlapping the pixel part, and the first inorganic insulating layer and the second inorganic insulating layer are arranged in a region overlapping the pixel part and the wiring part,
the sensing part comprises:
a first detection electrode arranged at an upper side of the first inorganic insulating layer and at a lower side of the second inorganic insulating layer; and
a second detection electrode arranged at an upper side of the second inorganic insulating layer,
wherein
the first wiring included in the wiring part is electrically connected to the first detection electrode at an opening provided in the second inorganic insulating layer, and the first wiring extends to an outer region of the second inorganic insulating layer and is electrically connected to the second terminal.

2. The display device according to claim 1, wherein
the first detection electrode is arranged between the first inorganic insulating layer and the organic insulating layer.

3. The display device according to claim 1, wherein
the first detection electrode is arranged between the second inorganic insulating layer and the organic insulating layer.

4. The display device according to claim 1, wherein
an interlayer insulating layer arranged between the substrate and the first inorganic insulating layer, and
the interlayer insulating layer includes an opening region passing through the interlayer insulating layer between the second terminal and the opening.

5. The display device according to claim 1, wherein
an interlayer insulating layer arranged between the substrate and the first inorganic insulating layer, and
the interlayer insulating layer includes an opening region passing through the interlayer insulating layer between the pixel part and the opening.

6. The display device according to claim 1, wherein
an interlayer insulating layer arranged between the substrate and the first inorganic insulating layer, and
the interlayer insulating layer includes an opening region passing through the interlayer insulating layer between the first terminal and the second terminal.

7. The display device according to claim 1, wherein
the first detection electrode and the second detection electrode comprise a laminated structure including a first titanium layer, an aluminum layer, and a second titanium layer, and have a mesh shape.

8. The display device according to claim 1, wherein
the first detection electrode comprises a laminated structure including a first titanium layer, an aluminum layer and a second titanium layer, and has a mesh shape, and
the second detection electrode includes a transparent electrode, and has a diamond shape.

9. The display device according to claim 1, wherein
the first detection electrode includes a transparent electrode, and has a diamond shape, and
the second detection electrode comprises a laminated structure including a first titanium layer, an aluminum layer and a second titanium layer, and has a mesh shape.

10. A manufacturing method for a display device, the method comprising:
forming a pixel part arranged a plurality of pixels on a substrate having an insulating surface;
forming a terminal part including a first terminal in a region outside the pixel part on the insulating surface;
forming a second terminal between the pixel part and the terminal part on the insulating surface;
forming a first inorganic insulating layer covering the pixel part;
forming a first detection electrode layer extending in a first direction on the first inorganic insulating layer;
forming an organic insulating layer covering the first detection electrode layer;
forming a second inorganic insulating layer covering the organic insulating layer;
removing the first inorganic insulating layer and the second inorganic insulating layer on the second terminal, and forming an opening exposing the first detection electrode layer in the second insulating layer; and
forming a second detection electrode layer extending in a second direction intersecting with the first direction on the second inorganic insulating layer, and forming a first wiring connected to the first detection electrode and the second terminal in the opening provided in the second inorganic insulating layer.
